(19) United States
(12) Patent Application Publication
(10) Pub. No.: US 2021/0114170 A1
(43) Pub. Date: Apr. 22, 2021

(54) CONTAINER FOR STORING SLURRY HAVING FUMED SILICA PARTICLES AND CMP APPARATUS HAVING THE SAME

(71) Applicant: XIA TAI XIN SEMICONDUCTOR (QING DAO) LTD., Qingdao (CN)

(72) Inventor: SUN-WUNG LEE, Singapore (SG)

(21) Appl. No.: 16/660,736

(22) Filed: Oct. 22, 2019

(51) Int. Cl. B24B 57/02; C09G 1/02; H01L 21/67

(52) U.S. Cl. CPC B24B 57/02; H01L 21/67017; C09G 1/02

(57) ABSTRACT

The present disclosure provides a container for storing slurry having fumed silica particles. The container includes a main body having an inner space for accommodating the slurry, and a filter disposed in the inner space of the main body. The filter is a porous membrane having a plurality of pores. The filter has an upper surface and a bottom surface. The plurality of pores has a pore size distribution decreasing from the upper surface to the bottom surface.

### FIELD

The present disclosure generally relates to a container for fumed silica slurry.

More specifically, the present disclosure relates to a fumed silica slurry container that has a filter to prevent agglomerated large particles from becoming re-suspended into the slurry.

### BACKGROUND

Chemical mechanical polishing or chemical mechanical planarization (CMP) is a process whereby a semiconductor wafer is held in a retaining ring against a rotating polishing surface, or moved relative to the polishing surface, under controlled conditions of temperature, pressure, and chemical composition. The polished surface, which may be a planar pad formed of a relatively soft and porous material such as a blown polyurethane, is wetted with a chemically reactive and abrasive aqueous slurry. The aqueous slurry, which may be either acidic or basic, typically includes abrasive particles, reactive chemical agents such as a transition metal chelated salt or an oxidizer, and adjuvants such as solvents, buffers, and passivating agents. In such a slurry, salt or other agents may facilitate chemical etching actions, while the abrasive particles and the polishing pad together may facilitate mechanical polishing actions.

The type of abrasive material selected depends on the type of substrate to be polished. For polishing oxide layers of a wafer, slurries containing fumed silica particles are often used. The size of fumed silica particles in the slurry generally ranges from about 1 nanometer to several microns or higher. While particles on the order of 20 nanometers to a micron typically function well as abrasives, larger particles (e.g., agglomerates of particles) may scratch or cause other defects to the surface of the wafer. As such, an aging process is usually required to separate the agglomerated particles in the slurry before use. During the aging process, the fumed silica slurry is introduced into a container and allowed to sit, and thereby causing agglomerated particles to separate from the slurry under the influence of gravity. The aging process usually takes about 30 days. When the fumed silica slurry is being transported in the containers, the agglomerated particles may become re-suspended into the slurry, and an additional aging process of 30 to 90 days is required before the slurry is available for use.

Accordingly, there remains a need to provide a container for fumed silica slurry to overcome the aforementioned problems.

### SUMMARY

The present disclosure is directed to a container for fumed silica slurry that can prevent agglomerated large particles from becoming re-suspended into the slurry.

An implementation of the present disclosure provides a container for storing slurry having fumed silica particles. The container includes a main body having an inner space for accommodating the slurry, and a filter disposed in the inner space of the main body. The filter is a porous membrane having a plurality of pores. The filter has an upper surface and a bottom surface. The plurality of pores has a pore size distribution decreasing from the upper surface to the bottom surface.

Another implementation of the present disclosure provides a chemical mechanical polishing (CMP) apparatus for polishing a wafer. The CMP apparatus includes a platen, a retaining ring, a carrier head, a supply tube, and a container. The platen has a polishing pad for polishing the wafer by a slurry having fumed silica particles. The retaining ring is configured to hold the wafer. The carrier head is connected to the retaining ring and configured to rotate the retaining ring. The supply tube is configured to provide the slurry to the polishing pad of the platen. The container is configured to store the slurry and be connected to the supply tube. The container includes a main body having an inner space for accommodating the slurry, and a filter disposed in the inner space of the main body. The filter is a porous membrane having a plurality of pores. The filter has an upper surface and a bottom surface. The plurality of pores has a pore size distribution decreasing from the upper surface to the bottom surface.

As described above, the container of the implementations of the present disclosure includes a filter to prevent agglomerated large particles in the fumed silica slurry from becoming re-suspended into the slurry. Therefore, the container of the implementations of the present disclosure can avoid additional aging time for fumed silica slurries. Also, the container of the implementations of the present disclosure can increase service time of the filter assembly in the slurry supply tube and also reduce defects on the surface of the wafer.

### BRIEF DESCRIPTION OF THE DRAWINGS

Implementations of the present technology will now be described, by way of example only, with reference to the attached figures.

FIG. 1 is a schematic diagram of a CMP apparatus.

FIG. 2A is a perspective view of a container for storing a slurry having fumed silica particles according to an implementation of the present disclosure.

FIG. 2B is a cross-sectional view of the container in FIG. 2A along line A-A′.

FIG. 2C is an enlarged cross-sectional view showing a filter of the container in FIG. 2B.

FIG. 2D is a perspective view of a container according to another implementation of the present disclosure.

FIG. 3 is a flowchart of a method for providing a slurry having fumed silica particles to a CMP apparatus according to an implementation of the present disclosure.

### DETAILED DESCRIPTION

The present disclosure will now be described more fully hereinafter with reference to the accompanying drawings, in which example implementations of the disclosure are shown. This disclosure may, however, be embodied in many different forms and should not be construed as limited to the example implementations set forth herein. Rather, these example implementations are provided so that this disclosure will be thorough and complete, and will fully convey the scope of the disclosure to those skilled in the art. Like reference numerals refer to like elements throughout.

The terminology used herein is for the purpose of describing particular example implementations only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, actions, operations, elements, and/or components, but do not preclude the presence or addition of one or more other features, regions, integers, actions, operations, elements, components, and/or groups thereof.

It will be understood that the term “and/or” includes any and all combinations of one or more of the associated listed items. It will also be understood that, although the terms first, second, third etc. may be used herein to describe various elements, components, regions, parts and/or sections, these elements, components, regions, parts and/or sections should not be limited by these terms. These terms are only used to distinguish one element, component, region, part or section from another element, component, region, layer or section. Thus, a first element, component, region, part or section discussed below could be termed a second element, component, region, layer or section without departing from the teachings of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

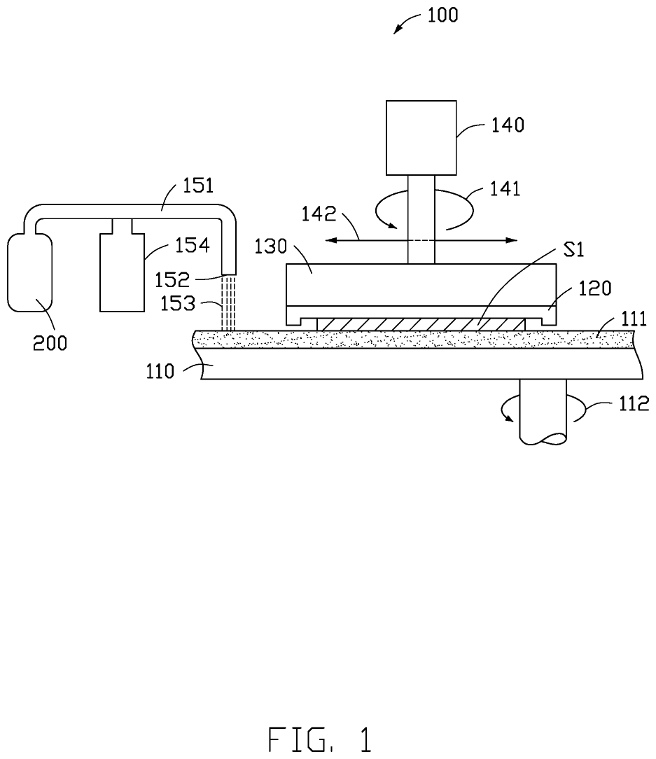

The description will be made as to the example implementations of the present disclosure in conjunction with the accompanying drawings in FIGS. 1 through 3. Reference will be made to the drawing figures to describe the present disclosure in detail, wherein depicted elements are not necessarily shown to scale and wherein like or similar elements are designated by same or similar reference numeral through the several views and same or similar terminology.

The present disclosure will be further described hereafter in combination with the accompanying figures.

Referring to FIG. 1, a schematic diagram of a chemical mechanical polishing (CMP) apparatus is illustrated. A CMP apparatus 100 includes a carrier head 130 and a retaining ring 120. A semiconductor wafer S1 is held in the retaining ring 120. A soft pad (not shown in FIG. 1) is positioned between the retaining ring 120 and the wafer S1, with the wafer S1 being held against the soft pad by partial vacuum or with an adhesive. The carrier head 130 is provided to be continuously rotated by a drive motor 140, in direction 141, and optionally reciprocated transversely in directions 142. Accordingly, the combined rotational and transverse movements of the wafer S1 are intended to reduce the variability in the material removal rate across the surface of the wafer S1. The CMP apparatus 100 further includes a platen 110, which is rotated in direction 112. A polishing pad 111 is mounted on the platen 110. As compared to the wafer S1, the platen 110 is provided with a relatively large surface area to accommodate the translational movement of the wafer S1 on the retaining ring 120 across the surface of the polishing pad 111. A supply tube 151 is mounted above the platen 110 to deliver a stream of polishing slurry 153, which is dripped onto the surface of the polishing pad 111 from a nozzle 152 of the supply tube 151. The slurry 153 may be gravity fed from a tank or reservoir (not shown), or otherwise pumped through the supply tube 151. Alternatively, the slurry 153 may be supplied from below the platen 110 such that it flows upwardly through the underside of the polishing pad 111. In another implementation, the slurry may be supplied in the retaining ring 120 by nozzles disposed in the retaining ring 120. If the particles in the slurry 153 form agglomeration of undesirable large particles, the wafer surface would be scratched when the wafer S1 is being polished. Therefore, the slurry 153 needs to be filtered to remove the undesirable large particles. Usually, a filter assembly 154 is coupled to the supply tube 151 to separate agglomerated or oversized particles. The CMP apparatus 100 further includes a container 200 for storing the slurry 153. The container 200 is connected to the supply tube 151 to continuously provide the slurry 153 to the platen 110. For storing slurries having fumed silica particles as abrasive materials, the container 200 will be described hereinafter.

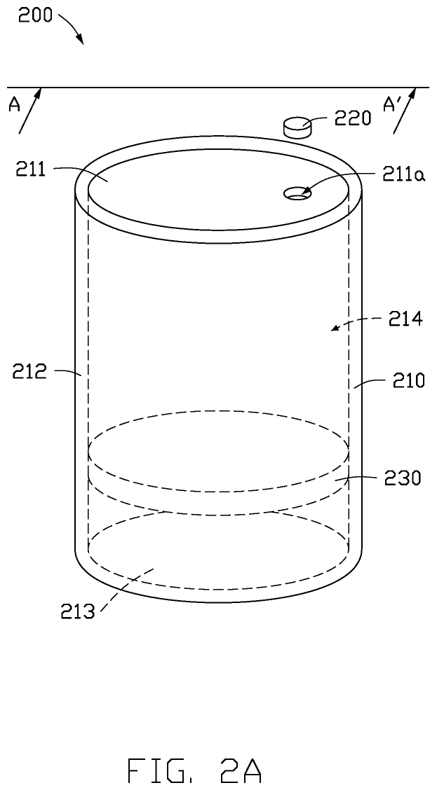

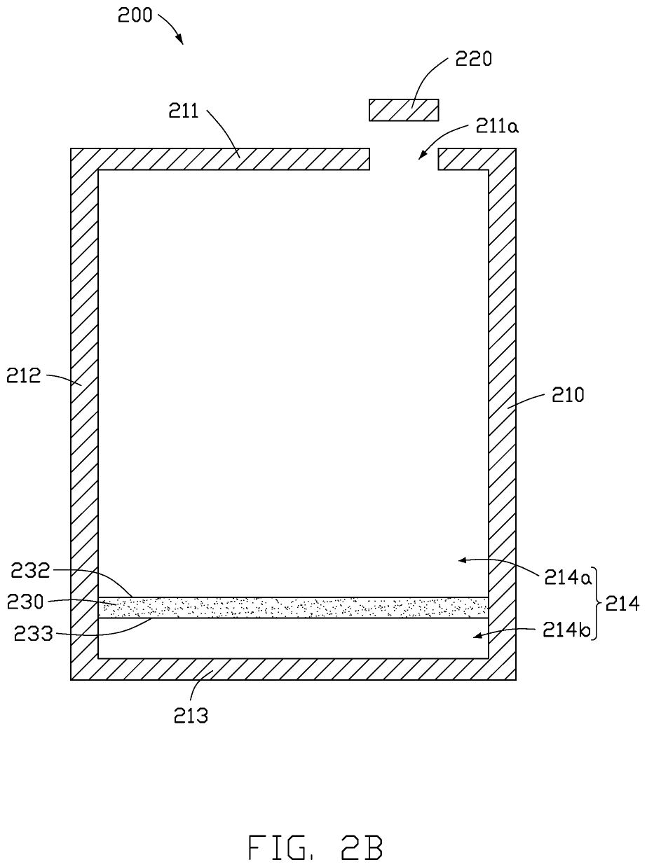

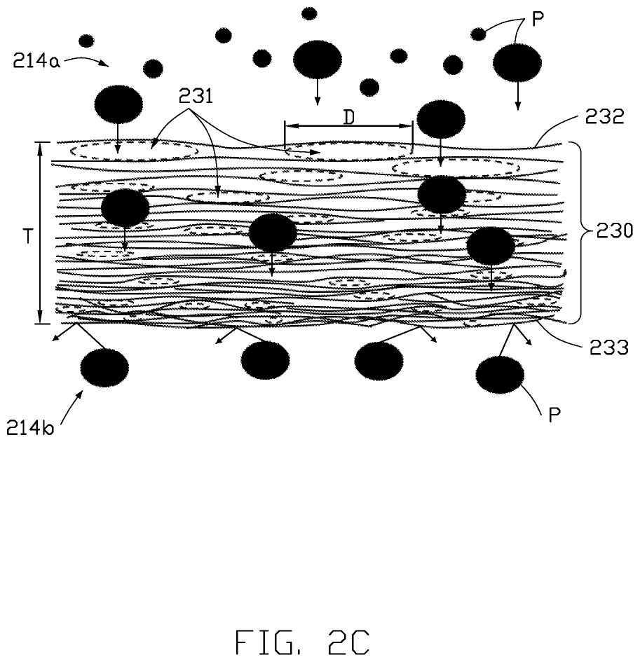

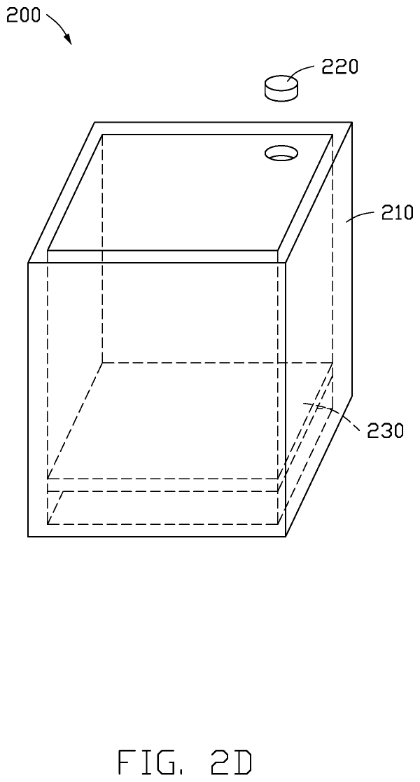

Referring to FIGS. 2A, 2B, and 2C, various views of the container 200 for storing slurries having fumed silica particles according to an implementation of the present disclosure are illustrated. FIG. 2A is a perspective view of the container 200. FIG. 2B is a cross-sectional view of the container 200. FIG. 2C is an enlarged cross-sectional view of a filter of the container 200 in FIG. 2B. As shown in FIGS. 2A and 2B, the container 200 includes a main body 210 having an inner space 214 for accommodating the slurry, and a filter 230 disposed in the inner space 214 of the main body 210. The main body 210 includes an upper wall 211, a side wall 212, and a bottom wall 213 enclosing the inner space 214. The main body 210 may be made of plastics or metals. In this implementation, the main body 210 has a cylindrical shape. The upper wall 211 of the main body 210 has an opening 211a for receiving and/or emptying the slurry. The container 200 may further include a cap 220 configured to seal the opening 211a of the upper wall 211 of the main body 210.

As shown in FIGS. 2B and 2C, the filter 230 is a porous membrane having a plurality of pores 231. In one implementation, the filter 230 is a fabric porous membrane. The filter 230 is made of polypropylene (PP), polybutylene, polyethylene terephthalate (PET), nylon, polyvinylidene fluoride (PVDF), or any combination thereof. In an implementation, the filter 230 is made of polypropylene (PP), such as fabric polypropylene membrane. The inner space 214 of the main body 210 is divided into a suspension space 214a and a sedimentation space 214b by the filter 230. Large fumed silica particles (e.g., agglomerated fumed silica particles that cause defects on the surface of the wafer) in the slurry tend to pass through the filter 230 due to the presence of gravity and precipitate in the sedimentation space 214b. Small fumed silica particles (e.g., non-agglomerated fumed silica particles useable for the polishing process) are suspended in the suspension space 214a. The filter 230 has an upper surface 232 and a bottom surface 233. The upper surface 232 of the filter 230 faces the suspension space 214a of the inner space 214, whereas the bottom surface 233 of the filter 230 faces the sedimentation space 214b of the inner space 214. In other words, the suspension space 214a is the space between the upper wall 211 of the main body 210 and the upper surface 232 of the filter 230. The sedimentation space 214b is the space between the bottom wall 213 of the main body 210 and the bottom surface 233 of the filter 230. The plurality of pores 231 has a decreasing pore size distribution from the upper surface 232 to the bottom surface 233. In other words, the pore size D (e.g., diameter) of the pores 231 close to the upper surface 232 is greater than the pore size D (e.g., diameter) of the pores 231 close to the bottom surface 233 of the filter 230. The filter 230 has a thickness T ranging from 0.1 to 5 centimeters (cm). The plurality of pores 231 close to the upper surface 232 of the filter 230 has a pore size D ranging from 20 to 30 microns (μm). The plurality of pores 231 close to the bottom surface 233 of the filter 230 has a pore size D ranging from 4 to 6 μm.

As shown in FIGS. 2B and 2C, when the slurry is introduced into the container 200 from the opening 211a. At first, fumed silica particles P in the slurry are suspended in the suspension space 214a. During the aging process, large particles P (e.g., agglomerated particles) pass through the filter 230 due to the presence of gravity and precipitate in the sedimentation space 214b, while small particles P (e.g., non-agglomerated particles) remain suspended in the suspension space 214a. When the slurry is transported in the container 200, impacts or vibrations during the transportation process may agitate the large particles P However, the large particles P are blocked by the filter 230 and remain in the sedimentation space 214b. In other words, the filter 230 prevents the large particles P in the sedimentation space 214b from re-suspending in the slurry of the suspension space 214a. Therefore, when the slurry is transported to the manufacturing site for use in polishing process, no additional aging process is required.

Referring to FIG. 2D, a container of the present disclosure according to another implementation is illustrated. In this implementation, the container 200 in FIG. 2D may be substantially similar to the container 200 described in FIGS. 2A through 2C, except the main body 210 of the container 200 in FIG. 2D has a rectangular shape. The other elements of the container 200 may be referred to FIGS. 2A to 2C and previous implementations without further description herein.

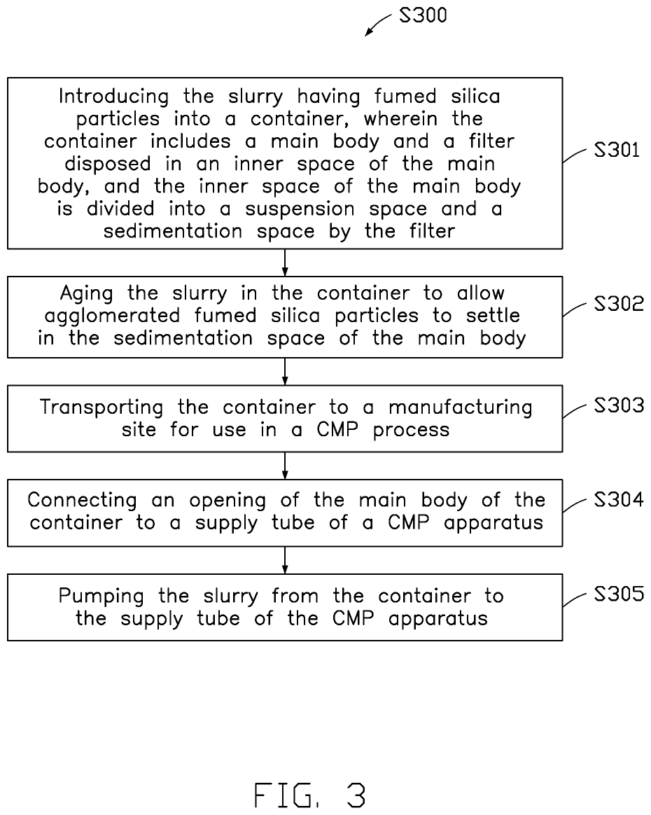

Referring to FIG. 3, FIG. 3 is a flowchart of a method for providing a slurry having fumed silica particles to a CMP apparatus according to an implementation of the present disclosure The CMP apparatus may correspond to the CMP apparatus 100 of FIG. 1. In FIG. 3, a method S300 includes actions S301 to S305.

In action S301, the slurry having fumed silica particles is introduced into a container. The container may correspond to the container 200 of FIGS. 2A to 2D. As shown in FIGS. 2A to 2D, the container 200 includes the main body 210 having the inner space 214 for accommodating the slurry, and the filter 230 disposed in the inner space 214 of the main body 210. The main body 210 includes the upper wall 211, the side wall 212, and the bottom wall 213 enclosing the inner space 214. The main body 210 can be made of plastics or metals. In one implementation, the main body 210 has a cylindrical shape. The upper wall 211 of the main body 210 has the opening 211a for receiving and/or emptying the slurry. The container 200 further includes the cap 220 configured to seal the opening 211a of the upper wall 211 of the main body 210. The filter 230 includes a porous membrane having the plurality of pores 231. The inner space 214 of the main body 210 is divided into the suspension space 214a and the sedimentation space 214b by the filter 230. The plurality of pores 231 has a decreasing pore size distribution from the upper surface 232 to the bottom surface 233.

In action S302, the slurry is aged in the container 200 to allow agglomerated fumed silica particles to settle in the sedimentation space 214b. The aging process may take about 30 days. Large particles in the slurry may cause defects on the surface of the wafer. During the aging process, large particles P (e.g., agglomerated particles) pass through the filter 230 due to the presence of gravity and precipitate in the sedimentation space 214b, while small particles P (e.g., non-agglomerated particles) remain suspended in the suspension space 214a.

In action S303, the container 200 is transported to a manufacturing site for use in a CMP process. Impacts or vibrations may occur during the transportation process. The large particles P may be agitated by the impacts or vibrations. However, the large particles P are be blocked by the filter 230 and remain in the sedimentation space 214b. In other words, the filter 230 prevents the large particles P in the sedimentation space 214b from re-suspending in the slurry of the suspension space 214a.

In action S304, the opening 211a of the container 200 is connected to a supply tube of a CMP apparatus. The CMP apparatus may correspond to the CMP apparatus 100 of FIG. 1. In action S305, the slurry is pumped from the container 200 through the opening 211a to the supply tube 151 of the CMP apparatus 100.

In another implementation, the present disclosure further provides a CMP apparatus for polishing a wafer. The CMP apparatus may correspond to the CMP apparatus 100 in FIG. 1. The CMP apparatus 100 includes the platen 110, the retaining ring 120, the carrier head 130, the supply tube 151, and the container 200. The platen 110 has the polishing pad 111 for polishing the wafer S1 by the slurry 153 having fumed silica particles. The retaining ring 120 is configured to hold the wafer. The carrier head 130 is connected to the retaining ring 120 and configured to rotate the retaining ring 120. The supply tube 151 is configured to provide the slurry 153 to the polishing pad 111 of the platen 110. The container 200 is configured to store the slurry 153 and be connected to the supply tube 151. The CMP apparatus 100 further includes the drive motor 140 connected to the carrier head 130, and the filter assembly 154 connected to the supply tube 151. The drive motor 140 rotates the carrier head 130 in the direction 141, and optionally reciprocated transversely in the directions 142. The filter assembly 154 is configured to filter large particles (e.g., agglomerated particles) in the slurry 153 to prevent causing defects on the surface of the wafer S1.

The details of the container 200 may be referred to FIGS. 2A to 2D. The container 200 includes the main body 210 having the inner space 214 for accommodating the slurry 153, and the filter 230 disposed in the inner space 214 of the main body 210. The main body 210 comprises the upper wall 211, the side wall 212, and the bottom wall 213 enclosing the inner space 214. The filter 230 includes a porous membrane having the plurality of pores 231. The filter 230 has the upper surface 232 and the bottom surface 233. The plurality of pores 231 has a pore size distribution decreasing from the upper surface 232 to the bottom surface 233. The upper wall 211 of the main body 210 of the container 200 has the opening 211a. The supply tube 151 is connected to the opening 211a of the container 200. The slurry 153 may be pumped from the suspension space 214a of the container 200 through the opening 211a to the supply tube 151. After an aging process, large particles P (e.g., agglomerated particles) in the slurry pass through the filter 230 under the influence of gravity and precipitate in the sedimentation space 214b, while small particles P (e.g., non-agglomerated particles) remain suspended in the suspension space 214a. When the slurry 153 in the container 200 is pumped into the supply tube 151, impacts or vibrations may occur. The large particles P are agitated by the impacts or vibrations. However, the large particles P are blocked by the filter 230 and remained in the sedimentation space 214b. In other words, the filter 230 prevents the large particles P in the sedimentation space 214b from re-suspending in the slurry of the suspension space 214a. Therefore, the large particles P in the slurry 153 are prevented from flowing into the supply tube 151, and hence increasing the service time of the filter assembly 154 and reducing defects on the surface of the wafer S1.

As described above, the containers according to the implementations of the present disclosure each include a filter to prevent agglomerated large particles in the fumed silica slurry from becoming re-suspended into the slurry. Therefore, the containers of the implementations of the present disclosure can eliminate additional aging time for fumed silica slurries. Also, the containers of the implementations of the present disclosure can increase service time of the filter assembly in the slurry supply tube, and reduce defects on the surface of the wafer.

The implementations shown and described above are only examples. Many details are often found in the art such as the other features of a container for storing slurry having fumed silica particles. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the implementations described above may be modified within the scope of the claims.

What is claimed is:

1. A container for storing slurry having fumed silica particles, comprising:
a main body having an inner space for accommodating the slurry; and
a filter disposed in the inner space of the main body,
wherein the filter includes a porous membrane having a plurality of pores, the filter has an upper surface and a bottom surface, the plurality of pores has a pore size distribution decreasing from the upper surface to the bottom surface.

2. The container of claim 1, wherein an upper wall of the main body has an opening for receiving or emptying the slurry.

3. The container of claim 2, further comprising a cap configured to seal the opening of the upper wall of the main body.

4. The container of claim 1, wherein the main body has a cylindrical shape.

5. The container of claim 1, wherein the main body has a rectangular shape.

6. The container of claim 1, wherein the filter is made of at least one of polypropylene, polybutylene, polyethylene terephthalate, nylon, and polyvinylidene fluoride.

7. The container of claim 6, wherein the filter is made of polypropylene.

8. The container of claim 1, wherein the filter has a thickness ranging from 0.1 cm to 5 cm.

9. The container of claim 1, wherein the plurality of pores close to the upper surface of the filter has a pore size ranging from 20 microns to 30 microns.

10. The container of claim 1, wherein the plurality of pores close to the bottom surface of the filter has a pore size ranging from 4 microns to 6 microns.

11. The container of claim 1, wherein the inner space of the main body is divided into a suspension space and a sedimentation space by the filter, the suspension space is between an upper wall of the main body and the upper surface of the filter, and the sedimentation space is between a bottom wall of the main body and the bottom surface of the filter.

12. A chemical mechanical polishing (CMP) apparatus for polishing a wafer, comprising:
a platen having a polishing pad for polishing the wafer by a slurry having fumed silica particles;
a retaining ring configured to hold the wafer;
a carrier head connected to the retaining ring and configured to rotate the retaining ring;
a supply tube configured to provide the slurry to the polishing pad of the platen; and
a container configured to store the slurry and be connected to the supply tube, comprising:
a main body having an inner space for accommodating the slurry; and
a filter disposed in the inner space of the main body, wherein the filter is a porous membrane having a plurality of pores, the filter has an upper surface and a bottom surface, the plurality of pores has a pore size distribution decreasing from the upper surface to the bottom surface.

13. The CMP apparatus of claim 12, further comprising a drive motor connected to the carrier head.

14. The CMP apparatus of claim 12, wherein an upper wall of the main body of the container has an opening, and the supply tube is connected to the opening of the container.

15. The CMP apparatus of claim 12, wherein the filter of the container includes at least one of polypropylene, polybutylene, polyethylene terephthalate, nylon, and polyvinylidene fluoride.

16. The CMP apparatus of claim 15, wherein the filter of the container is made of polypropylene.

17. The CMP apparatus of claim 12, wherein the filter of the container has a thickness ranging from 0.1 cm to 5 cm.

18. The CMP apparatus of claim 12, wherein the plurality of pores close to the upper surface of the filter of the container has a pore size ranging from 20 microns to 30 microns.

19. The CMP apparatus of claim 12, wherein the plurality of pores close to the bottom surface of the filter of the container has a pore size ranging from 4 microns to 6 microns.

20. The CMP apparatus of claim 12, wherein the inner space of the main body of the container is divided into a suspension space and a sedimentation space by the filter of the container, the suspension space is between an upper wall of the main body and the upper surface of the filter, and the sedimentation space is between a bottom wall of the main body and the bottom surface of the filter.
